(19) United States
(12) Patent Application Publication
(10) Pub. No.: US 2023/0275182 A1
(43) Pub. Date: Aug. 31, 2023

(54) DISPLAY DEVICE

(71) Applicant: KYOCERA Corporation, Kyoto-shi, Kyoto (JP)

(72) Inventor: Masaya TAMAKI, Yokohama-shi, Kanagawa (JP)

(21) Appl. No.: 18/011,066

(22) PCT Filed: Jun. 3, 2021
(86) PCT No.: PCT/JP2021/021245

§ 371 Date: Dec. 16, 2022

(30) Foreign Application Priority Data
Jun. 26, 2020 (JP) 2020-110902

(51) Int. Cl. H01L 33/10; H01L 33/46; H01L 33/62

(52) U.S. Cl. CPC H01L 33/10; H01L 33/46; H01L 33/62

(57) ABSTRACT

A display device includes a cavity structure and a light emitter. The cavity structure includes a third surface of a light guide as an image display surface, and a through-hole as a cavity in the third surface. The light emitter is in the through-hole. The third surface includes a light reflective surface in a portion other than the through-hole.

### TECHNICAL FIELD

The present disclosure relates to a display device.

### BACKGROUND OF INVENTION

A known liquid crystal display device is described in, for example, Patent Literature 1.

### CITATION LIST

### Patent Literature

Patent Literature 1: Japanese Unexamined Patent Application Publication No. 2004-125885

### SUMMARY

In an aspect of the present disclosure, a display device includes a cavity structure including a display surface, the display surface including a cavity and a light reflective surface in a portion of the display surface other than the cavity, and a light emitter in the cavity.

### BRIEF DESCRIPTION OF THE DRAWINGS

The objects, features, and advantages of the present disclosure will become more apparent from the following detailed description and the drawings.

FIG. 1 is a schematic plan view of a display device according to an embodiment of the present disclosure.

FIG. 2A is a cross-sectional view taken along line A1-A2 in FIG. 1.

FIG. 2B is a schematic cross-sectional view of a display device according to another embodiment of the present disclosure, corresponding to the cross-sectional view of FIG. 2A.

FIG. 3 is a schematic cross-sectional view of a display device according to an embodiment of the present disclosure.

FIG. 4 is a schematic cross-sectional view of a display device according to a variation of any of the embodiments of the present disclosure.

FIG. 5 is a schematic cross-sectional view of a display device according to a variation of any of the embodiments of the present disclosure.

FIG. 6 is a schematic cross-sectional view of a display device according to a variation of any of the embodiments of the present disclosure.

### DESCRIPTION OF EMBODIMENTS

The structure that forms the basis of a display device according to one or more embodiments of the present disclosure will be described. Patent Literature 1 describes a transmissive liquid crystal display device including a semi-transmissive reflective film (a semitransparent mirror) on the display surface of a liquid crystal panel. When the liquid crystal panel is being driven, the liquid crystal display device serves as a display device that displays images by emitting light from the liquid crystal panel. When the liquid crystal panel is not being driven, the liquid crystal display device serves as a mirror device that specularly reflects external light.

A known display device that also serves as a mirror uses external light at a utilization of about 50% at most. Thus, when serving as a mirror device, the device may fail to produce clear mirror images. A known display device that also serves as a mirror with a liquid crystal panel allows merely about 3 to 7% of backlight to transmit through the liquid crystal panel, and uses image light from the liquid crystal panel at a utilization of about 50% at most. Thus, when serving as a display device, the device may fail to display high-luminance images. To display high-luminance images, the device uses an increased amount of backlight and may increase power consumption.

A display device according to one or more embodiments of the present disclosure will now be described with reference to the accompanying drawings. Each figure referred to below illustrates main components and other elements of the display device according to one or more embodiments. In the embodiments of the present disclosure, the display device may include known components that are not illustrated, for example, circuit boards, wiring conductors, control integrated circuits (ICs), and large-scale integration (LSI) circuits.

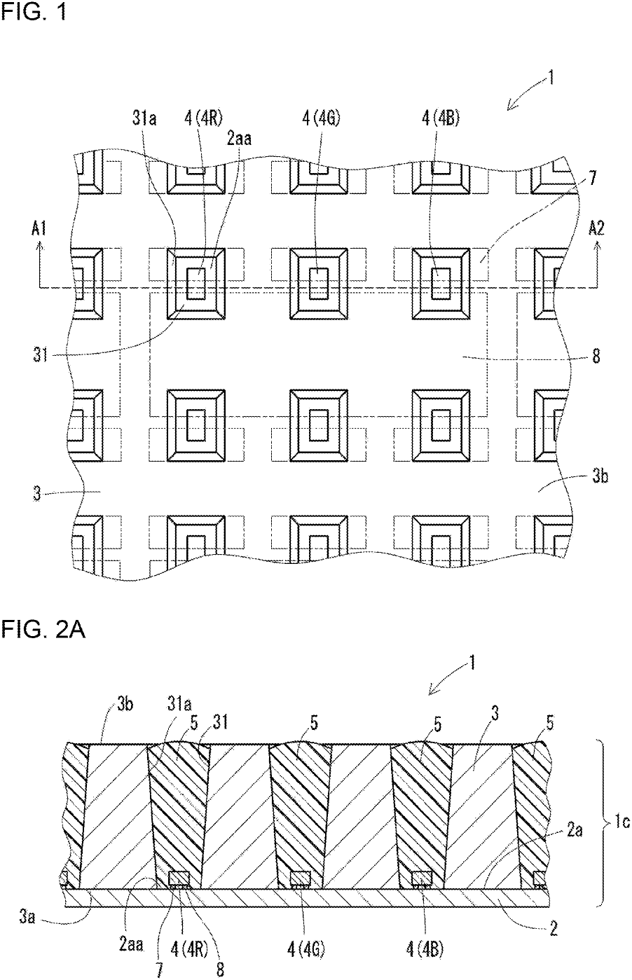

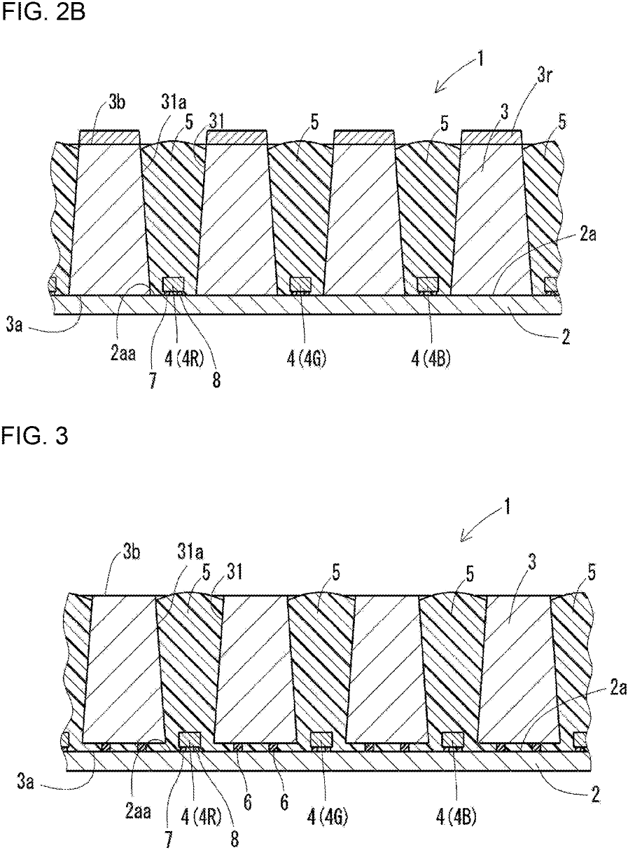

FIG. 1 is a plan view of a display device according to an embodiment of the present disclosure. FIG. 2A is a cross-sectional view taken along line A1-A2 in FIG. 1. FIG. 3 is a cross-sectional view of a display device according to an embodiment of the present disclosure. In the plan view of FIG. 1, transparent members are not illustrated. The cross-sectional views of FIGS. 2B and 3 correspond to the cross-sectional view of FIG. 2A.

In the embodiment of the present disclosure, as illustrated in, for example, FIG. 2A, the display device includes a cavity structure 1c and light emitters 4. The cavity structure 1c includes a third surface 3b of a light guide 3 as an image display surface, and through-holes 31 as cavities in the third surface 3b. The light emitters 4 are in the through-holes 31. The third surface 3b is a light reflective surface in a portion of the cavity structure 1c other than the through-holes 31. This structure produces the effects described below. The third surface 3b is a light reflective surface in the portion other than the through-holes 31. The device can thus serve as a mirror device when the light emitters 4 are not being driven, and can serve as the display device 1 when the light emitters 4 are being driven. The device includes no semitransparent mirror. Thus, when serving as a mirror device, the device can reflect external light on the third surface 3b with a high reflectance (e.g., higher than or equal to about 90%) and can produce clear mirror images (reflected images). The device includes the light emitters 4 that are self-luminous without using backlight. Thus, when serving as the display device 1, the device can use image light at a utilization of close to 100% and can display high-luminance images without increasing power consumption.

In the embodiment of the present disclosure, the display device includes the cavities defined by the through-holes 31 and exposed portions (element-mounting portions) 2aa of a first surface 2a of a substrate 2. More specifically, the element-mounting portions 2aa correspond to the bottom surfaces of the cavities, and the through-holes 31 correspond to the side surfaces of the cavities. The third surface 3b of the light guide 3 as the image display surface is the surface of the display device to be viewed externally by a viewer. For the display device used as a rearview mirror in an automobile, for example, a driver and a passenger of the automobile are viewers.

As illustrated in FIG. 2A, the display device 1 according to the present embodiment includes the substrate 2 and the light guide 3 together defining the cavity structure 1c. The display device 1 also includes multiple light emitters 4 and multiple transparent members 5. In the display device 1, the cavity structure 1c includes the substrate 2, the light guide 3, the through-holes 31, and the transparent members. The substrate 2 includes the first surface 2a. The light guide 3 is a plate and is on the first surface 2b. The light guide 3 includes a second surface 3a facing the first surface 2b and includes the third surface 3b as the display surface opposite to the second surface 3a. The through-holes 31 extend through the light guide 3 from the second surface 3a to the third surface 3b and expose portions of the first surface 2b. The transparent members are in the through-holes 31 and seal the light emitters 4. The light emitters 4 are on the exposed portions 2aa of the first surface 2a. The third surface 3b may be a mirror-like surface, or a reflector 3r (illustrated in FIG. 2B) may be on the third surface 3b.

The substrate 2 includes a main surface, or specifically the first surface 2a. The substrate 2 may be, for example, triangular, square, rectangular, trapezoidal, hexagonal, circular, oval, or in any other shape as viewed in plan (in other words, as viewed in a direction perpendicular to the first surface 2a).

The substrate 2 is made of, for example, a glass material, a ceramic material, a resin material, a metal material, an alloy material, or a semiconductor material. Examples of the glass material used for the substrate 2 may include borosilicate glass, crystallized glass, and quartz. Examples of the ceramic material used for the substrate 2 may include alumina (Al₂O₃), zirconia (ZrO₂), silicon nitride (Si₃N₄), silicon carbide (SiC), and aluminum nitride (AlN). Examples of the resin material used for the substrate 2 may include an epoxy resin, a polyimide resin, a polyamide resin, an acrylic resin, and a polycarbonate resin.

Examples of the metal material used for the substrate 2 may include aluminum (Al), magnesium (Mg) (specifically, high-purity magnesium with Mg content of 99.95% or higher), zinc (Zn), tin (Sn), copper (Cu), chromium (Cr), and nickel (Ni). Examples of the alloy material used for the substrate 2 may include duralumin, which is an aluminum alloy mainly containing aluminum (an Al-Cu alloy, an Al-Cu-Mg alloy, or an Al-Zn-Mg-Cu alloy), a magnesium alloy mainly containing magnesium (a Mg-Al alloy, a Mg-Zn alloy, or a Mg-Al-Zn alloy), titanium boride, stainless steel, and a Cu-Zn alloy. Examples of the semiconductor material used for the substrate 2 may include silicon, germanium, and gallium arsenide. For the substrate 2 made of a metal material, an alloy material, or a semiconductor material, an insulating layer of, for example, silicon oxide (SiO₂) or Si₃N₄ may be located on at least the first surface 2a of the substrate 2, and the light emitters 4 may be located on the insulating layer. This prevents electrical short-circuiting between an anode terminal and a cathode terminal of each light emitter 4.

For the substrate 2 made of a material with low light reflectivity, such as a glass material, a ceramic material, or a resin material, a light reflective film may be located on the first surface 2a. This allows light emitted from the light emitters 4 to the first surface 2a of the substrate 2 to be reflected above the through-holes 31, allowing a higher utilization of the light. This also allows the third surface 3b to be an efficient light reflective surface (mirror-like surface) with its entire area having high light reflectivity when the light emitters 4 are turned off. The light reflective film may be made of, for example, a metal material or an alloy material with a high reflectance of visible light. Examples of the metal material for the light reflective film include Al, silver (Ag), gold (Au), Cr, Ni, platinum (Pt), and Sn. Examples of the alloy material include duralumin, which is an aluminum alloy mainly containing aluminum (an Al-Cu alloy, an Al-Cu-Mg alloy, or an Al-Zn-Mg-Cu alloy). These materials have a light reflectance of about 90 to 95% for aluminum, 93% for silver, 60 to 70% for gold, 60 to 70% for chromium, 60 to 70% for nickel, 60 to 70% for platinum, 60 to 70% for tin, and 80 to 85% for an aluminum alloy. Aluminum, silver, gold, and an aluminum alloy may be used for the light reflective film.

For the substrate 2 with a drive circuit including a thin-film transistor (TFT), the light reflective film may be located nearer each light emitter 4 than the drive circuit. In this case, the light reflective film also serves as a light shield layer for a channel of the TFT, and reduces malfunction of the drive circuit caused by a light leakage current flowing through the channel. For the substrate 2 including the drive circuit on its first surface 2a, the light reflective film may be located on the drive circuit with an insulating layer in between. The insulating layer may be made of, for example, SiO₂ or Si₃N₄.

As illustrated in, for example, FIGS. 2A and 2B, the light guide 3 is located on the first surface 2a of the substrate 2. The light guide 3 is, for example, a plate or a block. The light guide 3 includes the second surface 3a facing the first surface 2a of the substrate 2, and the third surface 3b opposite to the second surface 3a. The light guide 3 may be, for example, shaped similarly to the substrate 2 and may be triangular, square, rectangular, trapezoidal, hexagonal, circular, oval, or in any other shape as viewed in plan. The substrate 2 and the light guide 3 may have the same shape as viewed in plan.

As illustrated in, for example, FIGS. 1, 2A, and 2B, the light guide 3 includes multiple through-holes 31 extending through the light guide 3 from the second surface 3a to the third surface 3b. The multiple through-holes 31 expose multiple portions (hereafter also referred to as element-mounting portions) 2aa of the first surface 2a. The multiple through-holes 31 may be arranged in a matrix as viewed in plan. The third surface 3b may have an aperture ratio (specifically, the ratio of the area of the multiple through-holes 31 to the area of the third surface 3b) of, for example, about 15 to 80%, about 20 to 40%, about 25 to 35%, or about 30%.

Each through-hole 31 includes an opening in the third surface 3b, and the opening may have a smaller area than the third surface 3b excluding the opening. For multiple through-holes 31, the area of the opening refers to the total area of the openings of the multiple through-holes 31. This structure allows the third surface 3b excluding the openings, or specifically the portion of the third surface 3b that reflects external light for the display device 1 to serve as a mirror device, to have a larger area than the openings as self-luminous portions. This reduces the difference in luminance and clarity between the reflected image on the display device 1 as a mirror device and the displayed image with light from the self-luminous element. The reduced difference reduces discomfort of the viewer.

The opening of each through-hole 31 may be, for example, square, rectangular, circular, oval, or in any other shape. As illustrated in, for example, FIG. 1, each through-hole 31 includes the opening in the third surface 3b that may have an outer edge surrounding the outer edge of the corresponding element-mounting portion 2aa as viewed in plan. In other words, each through-hole 31 includes the opening in the second surface 3a and the opening in the third surface 3b, and the opening in the third surface 3b may be larger than the opening in the second surface 3a. This structure facilitates output of light emitted from the light emitters 4 from the display device 1.

As illustrated in, for example, FIG. 2A, each through-hole 31 may have a section parallel to the third surface 3b being gradually smaller in the depth direction (the thickness direction of the light guide 3). In other words, each through-hole 31 may have a horizontal section gradually enlarging from the second surface 3a toward the third surface 3b. This structure further facilitates output of light emitted from the light emitters 4 from the display device 1. The radiant intensity distribution of light emitted outside through each through-hole 31 can be a highly directional pattern with a longitudinally oblong shape approximate to a cosine (cosθ) surface, with the maximum intensity direction substantially aligned with a normal to the first surface 2a and the third surface 3b. In other words, the radiant intensity distribution of light emitted outside through each through-hole 31 has a highly directional pattern with a longitudinally oblong shape approximate to a cosine surface, which follows Lambert’s cosine law. Lambert’s cosine law is the law by which the radiant intensity of light observed from an ideal diffuse radiator is directly proportional to the cosine of the angle θ between the direction of incident light and a normal to the radiating surface, or the first surface 2a and the third surface 3b in the display device 1 according to the present embodiment. The cosine surface herein refers to a radiant intensity distribution pattern of light in the shape of a cosine curve as viewed in a longitudinal section.

The light guide 3 may be thicker than the substrate 2. This increases the strength of the display device 1 including the substrate 2 and the light guide 3. Each through-hole 31 in the light guide 3 with this structure can be deep and can increase the number of reflections, on its inner surface, of light with the maximum intensity (the peak intensity) in the radiant intensity distribution of light emitted from the light emitter 4. Light with the maximum intensity may be reflected on the inner surface of the through-hole 31 multiple times. The light may be reflected about two to five times inclusive or another number of times. Light with the maximum intensity may be emitted in a direction inclining relative to a perpendicular to the surface of the element-mounting portion 2aa for the light emitter 4, or specifically, a direction inclining toward the opening of the through-hole 31 in the third surface 3b. This increases the directivity of light emitted outside through the through-hole 31. The substrate 2 may have a thickness of about 0.2 to 2.0 mm, and the light guide 3 may have a thickness of about 1.0 to 3.0 mm. However, the thicknesses are not limited to these values. The direction of light with the maximum intensity may be, but not limited to, at an angle of about 40 to 60° to the exposed portion 2aa of the first surface 2a.

The light guide 3 is made of, for example, a metal material, an alloy material, a semiconductor material, or a resin material. Examples of the metal material used for the light guide 3 may include Al, titanium (Ti), beryllium (Be), Mg (specifically, high-purity magnesium with Mg content of 99.95% or higher), Zn, Sn, Cu, iron (Fe), Cr, Ni, and Ag. Examples of the alloy material used for the light guide 3 may include duralumin, which is an aluminum alloy mainly containing aluminum (an Al-Cu alloy, an Al-Cu-Mg alloy, or an Al-Zn-Mg-Cu alloy), a magnesium alloy mainly containing magnesium (a Mg-Al alloy, a Mg-Zn alloy, or a Mg-Al-Zn alloy), a copper alloy mainly containing copper (a Cu-Zn alloy, a Cu-Zn-Ni alloy, a Cu-Sn alloy, or a Cu-Sn-Zn alloy), an iron alloy mainly containing iron (a Fe-Ni alloy, a Fe-Ni alloy with 36% nickel or Invar, a Fe-Ni-Co alloy or Kovar, a Fe-Cr alloy, or a Fe-Cr-Ni alloy), or titanium boride. Examples of the semiconductor material used for the light guide 3 may include silicon, germanium, and gallium arsenide. For the light guide 3 made of a metal material or an alloy material, the multiple through-holes 31 may be formed by, for example, punching or electroforming (plating). For the light guide 3 made of a semiconductor material, the multiple through-holes 31 may be formed by, for example, photolithography including dry etching.

The light guide 3 may be made of, for example, a glass material, a ceramic material, or a resin material. Examples of the glass material include borosilicate glass, crystallized glass, and quartz. Examples of the ceramic material include Al₂O₃, ZrO₂, Si₃N₄, SiC, and AlN. Examples of the resin material include an epoxy resin, a polyimide resin, a polyamide resin, an acrylic resin, and a polycarbonate resin.

The third surface 3b of the light guide 3 is exposed outside the display device 1. The third surface 3b is either a natural mirror-like surface with metallic luster or has a mirror finish to specularly reflect external light (specular reflection). For the third surface 3b being a natural mirror-like surface with metallic luster, the light guide 3 may be made of a metal material or an alloy material with a high reflectance of visible light. Examples of such materials include aluminum (with a light reflectance of about 90 to 95%), silver (with a light reflectance of about 93%), and an aluminum alloy (with a light reflectance of about 80 to 85%). For the third surface 3b having a mirror finish, any of known methods may be used, such as electrolytic polishing or chemical polishing. The third surface 3b may have a surface roughness Ra of, for example, about 0.01 to 0.1 µm. The third surface 3b may have a reflectance of visible light of, for example, about 85 to 95%.

The mirror-like surface of the third surface 3b may be achieved with another method. For example, the light guide 3 may be made of a semiconductor material, a glass material, a ceramic material, or a resin material with a low reflectance of visible light, and may include, on its third surface 3b, a reflective film made of a metal material or an alloy material with a high reflectance of visible light. In this case, the reflective film may be made of, for example, aluminum, silver, or an aluminum alloy.

FIG. 2B illustrates the light guide 3 including the reflector 3r on the third surface 3b. The reflector 3r may be a reflective film, a reflective sheet, or a solid reflector 3r. The reflective film may be formed by a thin film formation method such as plating, vapor deposition, or chemical vapor deposition (CVD). The reflective film may be formed by a thick film formation method such as firing and solidifying a resin paste containing particles of, for example, aluminum, silver, or gold. The reflective sheet may be bonded to the third surface 3b with, for example, an adhesive. The solid reflector 3r may be bonded to the third surface 3b with, for example, an adhesive, or may be fastened to the light guide 3 with a mechanical fastener such as a screw. The reflector 3r is made of, for example, a metal material or an alloy material with a high reflectance of visible light, such as aluminum (with a light reflectance of about 90 to 95%), silver (with a light reflectance of about 93%), and an aluminum alloy (with a light reflectance of about 80 to 85%).

In the structure of FIG. 2B, the light guide 3 may not be made of a metal material or an alloy material with a high reflectance of visible light, but may be made of, for example, a glass material, a ceramic material, or a resin material.

As illustrated in, for example, FIG. 3, for the light guide 3 made of a metal material or a semiconductor material, insulators 6 made of an electrically insulating material may be located between the first surface 2a of the substrate 2 and the second surface 3a of the light guide 3. This reduces short-circuiting between the light guide 3 and components on the first surface 2a such as electrodes or wiring conductors. The components such as the electrodes or the wiring conductors may be connected to the light emitters 4.

The insulators 6 may be made of a light-transmissive material or a light-shielding material. Examples of the light-transmissive material may include a resin material, such as an acrylic resin, a polycarbonate resin, and a polyethylene terephthalate resin. Examples of the light-shielding material may include a resin material mixed with a black pigment or carbon particles, and a resin material mixed with white ceramic particles such as titanium oxide particles or aluminum oxide particles. For the insulators 6 being light-shielding, light emitted from the light emitters 4 is less likely to partially leak to the adjacent through-holes 31 (reduces light leakage) through the insulators 6. An insulator 6 may extend across the entire area between the first surface 2a of the substrate 2 and the second surface 3a of the light guide 3, except the areas of the through-holes 31. This effectively reduces light leakage.

The light emitters 4 are mounted on the element-mounting portions 2aa. Each element-mounting portion 2aa may receive multiple light emitters 4. In some embodiments, the single first surface 2a may include multiple element-mounting portions 2aa each receiving the light emitter 4. The light emitters 4 may be, for example, self-luminous elements such as light-emitting diodes (LEDs), organic LEDs, or semiconductor laser diodes. In the present embodiment, the light emitters 4 are LEDs. The LEDs may be micro-LEDs. Each micro-LED mounted on the element-mounting portion 2aa may be rectangular as viewed in plan with each side having a length of about 1 to 100 µm inclusive, or about 5 to 20 µm inclusive.

The display device 1 includes anode electrodes 7 and cathode electrodes 8 located on the element-mounting portions 2aa. Each anode electrode 7 is electrically connected to the anode terminal of the corresponding light emitter 4. Each cathode electrode 8 is electrically connected to the cathode terminal of the corresponding light emitter. The anode electrode 7 and the cathode electrode 8 are connected to a drive circuit (not illustrated) for controlling, for example, the emission or non-emission state and the light intensity of the light emitter 4.

The drive circuit is located on the substrate 2. The drive circuit includes, for example, a TFT and a wiring conductor. The TFT may include, for example, a semiconductor film (or a channel) of amorphous silicon (a-Si) or low-temperature polycrystalline silicon (LTPS), and three terminals that are a gate electrode, a source electrode, and a drain electrode. The TFT serves as a switching element that switches conduction and non-conduction between the source electrode and the drain electrode based on the voltage applied to the gate electrode. The drive circuit may be located on the substrate 2, or between multiple insulating layers of, for example, silicon oxide or silicon nitride located on the substrate 2. The drive circuit may be formed by a thin film formation method such as CVD.

The drive circuit may be located on one main surface (the first surface 2a) of the substrate 2. In this case, the drive circuit may be located at, for example, an edge (a frame) of the first surface 2a. The drive circuit may be located on the other main surface opposite to the above main surface of the substrate 2. This structure can reduce or eliminate the frame of the first surface 2a.

The light emitter 4 may be electrically and mechanically connected to the anode electrode 7 and the cathode electrode 8 by flip chip connection using a conductive connector, such as an anisotropic conductive film (ACF), a solder ball, a metal bump, or a conductive adhesive. The light emitter 4 may be electrically and mechanically connected to the anode electrode 7 and the cathode electrode 8 using a conductive connector such as a bonding wire.

The display device 1 may include multiple pixel units arranged in a matrix. Each pixel unit may include multiple light emitters 4. The multiple light emitters 4 in each pixel unit may include, for example, a light emitter 4R that emits red light, a light emitter 4G that emits green light, and a light emitter 4B that emits blue light. This allows the display device 1 to display full-color gradation.

Each pixel unit may include, in addition to the light emitters 4R, 4G, and 4B, at least one of a light emitter 4 that emits yellow light or a light emitter 4 that emits white light. This improves the color rendering and color reproduction of the display device 1. Each pixel unit may include, instead of the light emitter 4R that emits red light, a light emitter 4 that emits orange, red-orange, red-violet, or violet light. Each pixel unit may include, instead of the light emitter 4G that emits green light, a light emitter 4 that emits yellow-green light.

As illustrated in, for example, FIG. 3, the transparent members 5 are in the through-holes 31. The transparent members 5 seal the light emitters 4. This reduces the likelihood of the light emitters 4 being misaligned or separate from the corresponding element-mounting portions 2aa, thus improving the reliability of the display device 1.

The transparent members 5 are made of, for example, a transparent resin material. Examples of the transparent resin material used for the transparent members 5 may include a fluororesin, a silicone resin, an acrylic resin, a polycarbonate resin, and a polymethyl methacrylate resin. Each transparent member 5 may contain scattering particles of, for example, a metal material or a glass material.

Each transparent member 5 may include a convexly curved surface adjacent to the third surface 3b as the display surface (the light-emitting surface). In this case, the light-emitting surface of the transparent member 5 can effectively serve as a lens for concentrating the emitted light. The curved surface may include, for example, a partial sphere, a partial ellipsoid, or a partial hyperboloid, or may combine multiple types of curved surfaces, or may combine a curved surface and a flat surface.

In the embodiment of the present disclosure, the display device 1 serves as a mirror device that specularly reflects external light on the third surface 3b when, for example, the light emitters 4 are not being driven. A known display device includes a semitransparent mirror to reflect external light, and uses external light at a utilization of about 50% at most. Such a device may fail to produce clear mirror images. The utilization of external light refers to the percentage of light that is specularly reflected by the reflective surface to form a reflected image (mirror image) relative to external light incident on the light reflective surface of the mirror. In the display device 1, the third surface 3b has an aperture ratio of about 20 to 40% and a reflectance of about 85 to 95%. The display device 1 can thus use external light at a utilization of higher than or equal to 50% (0.6 × 0.85 × 100 = 51% to 0.8 × 0.95 × 100 = 76%). Thus, when serving as a mirror device, the display device 1 can use external light at a higher utilization and form clear mirror images.

The third surface 3b as the display surface may include a curved surface being curved outward. This allows the display device 1 to provide a wide view of the external environment, such as a rear area, when serving as a mirror device. In other words, the display device 1 provides a wide field of view and may be used as, for example, a rearview mirror of an automobile or another vehicle. The curved surface may include, for example, a partial sphere, a partial ellipsoid, or a partial hyperboloid, or may combine multiple types of curved surfaces, or may combine a curved surface and a flat surface, or may combine a flat surface and a flat surface. For the curved surface combining a curved surface and a flat surface, the combined surface may include the flat surface in its central portion and the curved surface in its peripheral portion. In this case, the viewer can easily view a near location (e.g., inside an automobile) using the central portion, and easily view a distant location (e.g., outside an automobile) using the peripheral portion. The central portion may have an area of about 50 to 70% of the display surface area. The peripheral portion may have an area of about 50 to 30% of the display surface area. However, the areas of the portions are not limited to these. To achieve similar effects, the curved surface may include a flat surface in its central portion and a flat surface in its peripheral portion.

In the embodiment of the present disclosure, the display device 1 serves as a display device that displays images with light emitted from the light emitters 4 when the light emitters 4 are being driven. A known display device includes a semitransparent mirror on the display surface of a liquid crystal panel. Such a display device uses light from the liquid crystal panel at a utilization of about 50% at most, and uses backlight with the liquid crystal panel at a still lower utilization (e.g., about 3 to 7%). To display high-luminance images, such a display device uses an increased amount of backlight as a light source and may increase power consumption. The display device 1 allows substantially all the light emitted from the light emitters 4 as the light source to be output outside as image light. Thus, when serving as a display device, the display device 1 can use light emitted from the light emitters 4 at a greatly increased utilization. The display device 1 can thus display high-luminance images without increasing power consumption.

In the embodiment of the present disclosure, the display device 1 can form clear mirror images when serving as a mirror device, and can display high-luminance images without increasing power consumption when serving as a display device.

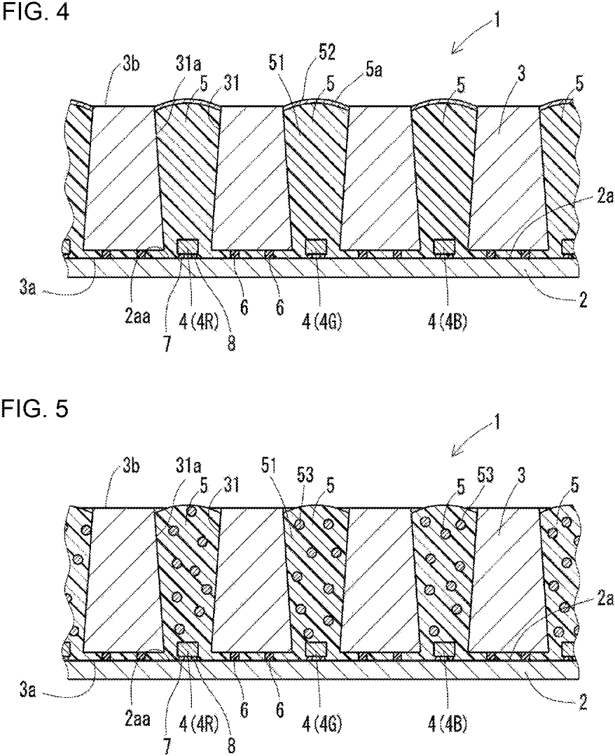

A display device according to a variation of any of the embodiments of the present disclosure will now be described. FIGS. 4 to 6 are each a cross-sectional view of a display device according to a variation of any of the embodiments of the present disclosure. The cross-sectional views of FIGS. 4 to 6 correspond to the cross-sectional views of FIGS. 2A, 2B, and 3.

As illustrated in, for example, FIG. 4, semi-transmissive reflective films 52 may be located on the surfaces of the transparent members 5 adjacent to the third surface 3b. More specifically, each transparent member 5 may include a body 51 made of a transparent resin material and the semi-transmissive reflective film 52 located on a surface 51a of the body 51 adjacent to the third surface 3b. The surface 51a of the body 51 adjacent to the third surface 3b may be a surface of the body 51 in a portion surrounded by the outer edge of the opening of the corresponding through-hole 31 when the third surface 3b is viewed in plan. The semi-transmissive reflective films 52 reflect incident light partially. The semi-transmissive reflective films 52 may have a reflectance of, for example, about 10 to 40%.

Examples of the transparent resin material used for the bodies 51 include a fluororesin, a silicone resin, an acrylic resin, a polycarbonate resin, and a polymethyl methacrylate resin. The semi-transmissive reflective films 52 may be thin films of, for example, a metal material. Examples of the metal material used for the semi-transmissive reflective films 52 include aluminum, silver, and copper. The semi-transmissive reflective films 52 may be formed by, for example, sputtering, plasma-enhanced CVD (PECVD), or CVD. The semi-transmissive reflective films 52 may have the thicknesses controlled to adjust their reflectance and reflection (specular reflection, diffuse reflection, or other reflection). Each semi-transmissive reflective film 52 has a thickness of, for example, about 5 to 50 nm.

In the variation, the display device 1 can partially reflect external light incident on the transparent members 5 using the semi-transmissive reflective films 52. Thus, in the variation, the display device 1 can use external light at an increased utilization while maintaining the utilization of light emitted from the light emitters 4 at a level that allows high-luminance images to be displayed. In the variation, the display device 1 can thus form clearer reflected images when serving as a mirror device, and can display high-luminance images without increasing power consumption when serving as a display device.

As illustrated in, for example, FIG. 5, each transparent member 5 may include a body 51 made of a transparent resin material and transparent particles 53 dispersed in the body 51 and having a greater refractive index than the body 51.

Examples of the transparent resin material for the bodies 51 include a fluororesin, a silicone resin, and an acrylic resin. Each body 51 may have a refractive index of, for example, about 1.35 to 1.7. The transparent particles 53 may be made of, for example, a transparent resin material. Examples of the transparent resin material used for the transparent particles 53 include a polycarbonate resin and a polymethyl methacrylate resin. The transparent particles 53 may have a refractive index of, for example, about 1.4 to 2.5.

The transparent particles 53 may be made of, for example, an inorganic oxide such as silica, titanium oxide, indium tin oxide, or zinc oxide, or a glass material such as borosilicate glass, phosphate glass, or silicate glass.

In the variation, the display device 1 can easily guide light emitted from the light emitters 4 to the openings of the through-holes 31 in the third surface 3b by partially refracting the light using the transparent particles 53. Thus, in the variation, the display device 1 can use light emitted from the light emitters 4 at an increased utilization. In the variation, the display device 1 can thus form clear mirror images when serving as a mirror device, and can display high-luminance images without increasing power consumption when serving as a display device.

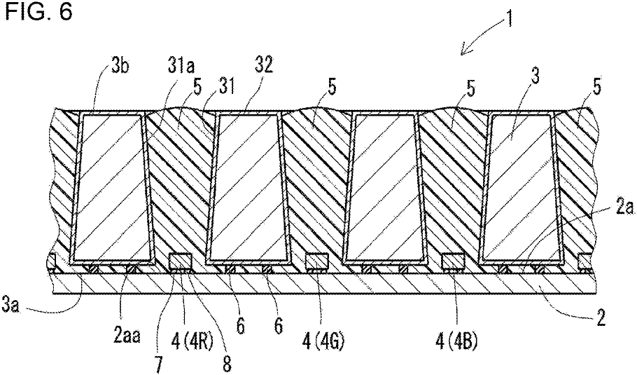

As illustrated in, for example, FIG. 6, a reflective film 32 may be located on the second surface 3a, the third surface 3b, and inner surfaces 31a of the through-holes 31 of the light guide 3. The reflective film 32 may be separately located on each of the second surface 3a, the third surface 3b, and the inner surfaces 31a of the through-holes 31, or may continuously extend on these surfaces. The reflective film 32 located on the third surface 3b corresponds to the reflector 3r in FIG. 2B. The reflective film 32 is made of, for example, a metal material or an alloy material. Examples of the metal material used for the reflective film may include Al, Ag, and Au. Examples of the alloy material may include an Al alloy.

The reflective film 32 may be formed on the second surface 3a, the third surface 3b, and the inner surfaces 31a of the multiple through-holes 31 of the light guide 3 by a thin film formation method such as CVD, vapor deposition, or plating. The reflective film 32 may be formed by a thick film formation method such as firing and solidifying a resin paste containing particles of, for example, aluminum, silver, or gold. The reflective film 32 may be formed on the second surface 3a, the third surface 3b, and the inner surfaces 31a of the through-holes 31 of the light guide 3 by bonding a film containing, for example, aluminum, silver, gold, or an alloy of any of these metals. A protective film may be located on the outer surface of the reflective film 32 to reduce the decrease in the reflectance caused by oxidation of the reflective film 32.

The reflective film 32 can specularly reflect external light incident on the third surface 3b of the light guide 3 and can also reflect light emitted from the light emitters 4 with a high reflectance on the inner surfaces 31a of the through-holes 31. When the light emitted from the light emitters 4 partially enters between the substrate 2 and the light guide 3, the reflective film 32 on the second surface 3a of the light guide 3 can guide the light toward the inner surfaces 31a of the through-holes 31 to be emitted outside the through-holes 31. In the variation, the light guide 3 in the display device 1 is not limited to being made of a metal material, but may be made of, for example, a glass material, a ceramic material, a resin material, or a semiconductor material. Examples of the ceramic material for the light guide 3 include alumina, silicon nitride, and silicon carbide. Examples of the resin material for the light guide 3 include an epoxy resin, a polyimide resin, and a polyamide resin. Examples of the semiconductor material for the light guide 3 include silicon, germanium, and gallium arsenide.

In the variation, the display device 1 can thus form clear mirror images when serving as a mirror device, and can display high-luminance images without increasing power consumption when serving as a display device, similarly to the above display device 1.

In the variation, the light guide 3 with the multiple through-holes 31 in the display device 1 can be fabricated with a wider choice of methods. For the light guide 3 made of a glass material, the multiple through-holes 31 may be formed by, for example, photolithography including etching. For the light guide 3 made of a ceramic material, a powder of a raw ceramic material is mixed with an appropriate solvent to form slurry. The slurry is then shaped into a sheet using a known method such as doctor blading or calendering to form a ceramic green sheet (hereafter also referred to as a green sheet). The green sheet is then punched into a predetermined shape including multiple holes to be the multiple through-holes 31. The light guide 3 including the multiple through-holes 31 can be fabricated by stacking multiple punched green sheets and firing them together at a temperature of about 1600° C. For the light guide 3 made of a resin material, the light guide 3 including the multiple through-holes 31 can be fabricated by, for example, injection molding. For the light guide 3 made of a semiconductor material, the light guide 3 including the multiple through-holes 31 can be fabricated by, for example, dry etching.

In some embodiments, the light guide 3 is made of a conductive material, such as a metal material or an alloy material, or is made of a semiconducting material, such as a semiconductor material. In this case, the light guide 3 may be electrically connected to a cathode portion such as cathode wiring (or ground wiring) or a cathode electrode to serve as a cathode potential portion (or a ground potential portion). The light guide 3 with this structure has a large surface area and a large volume and can serve as a cathode potential portion (or a ground potential portion) with a stable potential. In some embodiments, the light guide 3 includes a body made of an insulating material, such as a glass material, a ceramic material, or a resin material, and includes a reflective film made of a conductive material, such as a metal material or an alloy material, located on the surface of the body. In this case, the reflective film may be electrically connected to a cathode portion such as cathode wiring or a cathode electrode to serve as a cathode potential portion (or a ground potential portion). The reflective film with this structure has a large surface area and can serve as a cathode potential portion (or a ground potential portion) with a stable potential.

In each of the above embodiments, the light guide 3 in the cavity structure 1c may be a transparent substrate made of, for example, a glass material or a transparent resin material and including the multiple through-holes 31. In this case, a reflector such as a reflective film may be located on the third surface 3b of the light guide 3.

The device with the above structure can be a transparent display that includes the substrate 2 made of a transparent material such as a glass material and the light guide 3 made of a transparent substrate. The device can also be a double-sided display including a reflector, such as a reflective layer or a reflective plate, located above the through-holes 31 to partially reflect light emitted from the light emitters 4 toward the back surface (opposite to the first surface 2a) of the substrate 2. In this case, for example, the multiple light emitters 4 may include light emitters 4 (referred to as light emitters 41) with no reflector above, and light emitters 4 (referred to as light emitters 42) with the reflector above. The light emitters 41 and 42 may alternate with each other. To display images on the front surface, driving is performed to cause the light emitters 41 to emit light and cause the light emitters 42 not to emit light. To display images on the back surface, driving is performed to cause the light emitters 41 not to emit light and cause the light emitters 42 to emit light. To display images on the front and back surfaces, driving is performed to cause the light emitters 41 and the light emitters 42 to emit light.

The reflector located above the through-holes 31 may be a reflective layer located on the upper surfaces of the transparent members 5 in the through-holes 31, or may be a reflective plate separate from the light guide 3 and located above the through-holes 31.

Multiple display devices according to any of the embodiments of the present disclosure may be joined together to form a composite display device (multi-display) by joining the side portions of adjacent display devices with, for example, an adhesive or screws.

In the above embodiments of the present disclosure, the display device includes the image display surface that is a light reflective surface in the portion other than the cavities. Thus, the device can serve as a mirror device when the light emitters are not being driven, and can serve as a display device when the light emitters are being driven. In the above embodiments of the present disclosure, the display device includes no semitransparent mirror. Thus, when serving as a mirror device, the device can reflect external light on the display surface with a high reflectance and can produce clear mirror images. The device includes the light emitters that are self-luminous without using backlight. Thus, when serving as a display device, the device can use image light at a utilization of close to 100% and can display high-luminance images without increasing power consumption.

Although the display devices according to the embodiments of the present disclosure have been described in detail, the display devices according to the embodiments of the present disclosure are not limited to those in the above embodiments, and may be changed or varied in various manners without departing from the spirit and scope of the present disclosure. The components described in the above embodiments may be entirely or partially combined as appropriate unless any contradiction arises.

### INDUSTRIAL APPLICABILITY

The display device according to one or more embodiments of the present disclosure can be used in various electronic devices. Such electronic devices include composite display devices (multi-displays), automobile route guidance systems (car navigation systems), ship route guidance systems, aircraft route guidance systems, indicators for instruments in vehicles such as automobiles, instrument panels, smartphones, mobile phones, tablets, personal digital assistants (PDAs), video cameras, digital still cameras, electronic organizers, electronic books, electronic dictionaries, personal computers, copiers, terminals for game devices, television sets, product display tags, price display tags, programmable display devices for industrial use, car audio systems, digital audio players, facsimile machines, printers, automatic teller machines (ATMs), vending machines, medical display devices, digital display watches, smartwatches, guidance display devices installed in stations or airports, and signage (digital signage) for advertisement.

REFERENCE SIGNS

| | |
|---|---|
| 1 | display device |
| 1 c | cavity structure |
| 2 | substrate |
| 2 a | first surface |
| 2 aa | exposed portion (element-mounting portion) of first surface |
| 3 | light guide |
| 3 a | second surface |
| 3 b | third surface |
| 3 r | reflector |
| 4, 4R, 4G, and 4B | light emitter |
| 5 | transparent member |
| 5 a | surface |
| 6 | insulator |
| 7 | anode electrode |
| 8 | cathode electrode |
| 31 | through-hole |
| 31 a | inner surface |
| 32 | reflective film |
| 51 | body |
| 51 a | surface |
| 52 | semi-transmissive reflective film |
| 53 | transparent particle |

1. A display device, comprising:
a cavity structure including a display surface, the display surface including a cavity and a light reflective surface in a portion of the display surface other than the cavity; and
a light emitter in the cavity.

2. The display device according to claim 1, wherein
the cavity structure includes
a substrate including a first surface with an exposed portion, and the light emitter on the exposed portion of the first surface,
a light guide that is a plate, and is on the first surface, the light guide including a second surface facing the first surface, and a third surface as the display surface opposite to the second surface,
a through-hole defining the cavity extending through the light guide from the second surface to the third surface and exposing a portion of the first surface, and
a transparent member in the through-hole and sealing the light emitter, and
the third surface includes a mirror-like surface, or the cavity structure includes a reflector on the third surface.

3. The display device according to claim 2, wherein
the transparent member includes a semi-transmissive reflective film on a surface of the transparent member adjacent to the third surface.

4. The display device according to claim 2, wherein
the transparent member contains transparent particles dispersed in the transparent member, the transparent particles having a greater refractive index than a refractive index of other parts of the transparent member.

5. The display device according to claim 2, wherein
the light guide includes a reflective film on the second surface, the third surface, and an inner surface of the through-hole.

6. The display device according to claim 2, wherein
the through-hole includes an opening in the third surface, and the opening has a smaller area than the third surface excluding the opening.

7. The display device according to claim 2, wherein
the through-hole includes an opening in the second surface and an opening in the third surface, and the opening in the third surface is larger than the opening in the second surface.

8. The display device according to claim 7, wherein
the through-hole has a horizontal section gradually enlarging from the second surface toward the third surface.

9. The display device according to claim 2, wherein
the light guide is thicker than the substrate.

10. The display device according to claim 2, wherein
the light emitter emits light with a maximum intensity in a radiant intensity distribution to be reflected a plurality of times on an inner surface of the through-hole.

11. The display device according to claim 2, further comprising:
an insulator between the first surface of the substrate and the second surface of the light guide.

12. The display device according to claim 11, wherein
the substrate includes wiring on the first surface directly below the insulator, and the wiring is connected to the light emitter.

13. The display device according to claim 12, wherein
the insulator is light-shielding.

14. The display device according to claim 1, wherein
the display surface includes a curved surface that is curved outward.

15. The display device according to claim 2, wherein
each of the substrate and the light guide comprises a transparent material.

16. The display device according to claim 15, wherein
the display device comprises the through-hole in plurality, and
the plurality of through-holes includes a through-hole with a reflector located above the through-hole to partially reflect light emitted from the light emitter toward the substrate, and includes a through-hole without the reflector.

17. The display device according to claim 1, wherein
the light emitter includes a micro-light-emitting diode.
